(19) United States
(12) Patent Application Publication
(10) Pub. No.: US 2008/0137315 A1
(43) Pub. Date: Jun. 12, 2008

(54) Electronic component device and method of mounting electronic component

(75) Inventor: Eiji Takaike, Nagano (JP)

Correspondence Address: KRATZ, QUINTOS & HANSON, LLP, 1420 K Street, N.W., Suite 400, WASHINGTON, DC, 20005, US

(73) Assignee: SHINKO ELECTRIC INDUSTRIES CO., LTD., Nagano-shi (JP)

(21) Appl. No.: 11/984,005

(22) Filed: Nov. 13, 2007

(30) Foreign Application Priority Data
Dec. 11, 2006 (JP) 2006-332975

(51) Int. Cl. H05K 7/02; B23P 11/00

(52) U.S. Cl. 361/771; 29/428

(57) ABSTRACT

An electronic component device includes a wiring substrate having a wiring pattern, an electronic component mounted on the wiring pattern of the wiring substrate and provided with an electrode arranged on a side surface thereof, and a gold bump provided on the wiring pattern in side neighborhood of the electrode of the electronic component and bonded to the electrode of the electronic component and the wiring pattern, and the electrode of the electronic component is electrically connected to the wiring pattern through the gold bump, and the gold bump is formed by a wire bump method.

### CROSS-REFERENCE TO RELATED APPLICATIONS

This application is based on and claims priority of Japanese Patent Application No.2006-332975 filed on Dec. 11, 2006, the entire contents of which are incorporated herein by reference.

### BACKGROUND OF THE INVENTION

1. Field of the Invention

The present invention relates to an electronic component device and a method of mounting an electronic component, and more particularly to an electronic component device constructed by mounting an electronic component such as a semiconductor device or a capacitor on a wiring substrate and a method of mounting the same.

2. Description of the Related Art

In the prior art, there is an electronic component device constructed by mounting an electronic component such as a semiconductor device or a capacitor on a wiring substrate. The electronic component is bonded to a wiring pattern of the wiring substrate by mainly using solder, thereby being mounted. As shown in FIG. 1, when a capacitor component 400 having a pair of electrodes 300 is mounted, solder is printed on a wiring pattern 200 of a wiring substrate 100, then the capacitor component 400 is arranged above the wiring substrate 100, and finally the pair of the electrodes 300 of the capacitor component 400 are bonded to the wiring pattern 200 with solder 220 by reflowing the solder 220 with heat.

As the arts related to this, Patent Literature 1 (Japanese Patent Application Laid-open Publication No. 2005-216884) discloses that a plurality of first chip components (e.g., chip capacitors) each having a pair of electrodes are mounted on a wiring pattern of a circuit substrate by solder, and second chip components (e.g., chip resistors) are mounted on the first chip components in a multilayer stack structure.

Also, Patent Literature 2 (Japanese Patent Application Laid-open Publication No. 2000-261123) discloses a mounting structure in which a chip resistor is arranged on a printed wiring board via thick glass film functioning as a spacer in between, and component electrodes on the side surfaces of the chip resistor are bonded to a soldering pad of the printed wiring board by solder.

Recently, a higher-density and higher-performance of electronic component device are demanded, and hence to mount a smaller-sized electronic component on a wiring substrate is required. However, the electronic component of a smaller size (of, for example, not more than 0.6 mm×0.3 mm) causes various problems when such electronic component is mounted to be bonded by solder.

In the case that the capacitor component 400 as mentioned above and shown in FIG. 1 is mounted, a lifting failure in which the one end side of the capacitor component 400 is lifted as shown in FIG. 2A is caused, or alignment due to the surface tension of the solder 220 is not effective enough, so that the capacitor component 400 is mounted in a misaligned position as shown in FIG. 2B. Furthermore, as shown in FIG. 2C, it possible to cause a bridge failure in which the fluidic solder 220 bridges between the pair of the electrodes 300 of the capacitor component 400, and thereby an electrical short circuit occurs therebetween.

### SUMMARY OF THE INVENTION

It is an object of the present invention to provide an electronic component device and a method of mounting an electronic component, in which an electronic component can be mounted on a wiring substrate with high reliability, even if the electronic component is of an extremely small size.

The present invention is concerned with an electronic component device, which includes a wiring substrate having a wiring pattern, an electronic component mounted on the wiring pattern of the wiring substrate and provided with an electrode on a side surface thereof, and a gold bump provided on the wiring pattern of side neighborhood of the electrode of the electronic component and bonded to the electrode of the electronic component and the wiring pattern, wherein the electrode of the electronic component is electrically connected to the wiring pattern through the gold bump.

According to the present invention, the electronic component (such as a semiconductor device or a capacitor component) provided with the electrode on a side surface thereof is mounted on the wiring pattern of the wiring substrate, and the electrode of the electronic component is electrically connected to the wiring pattern of the wiring substrate through the gold bump provided in side neighborhood of the electrode.

In the present invention, unlike a bonding method using fluidic solder, since the gold bump hardly flow, there is no possibility that a lifting failure, a misalignment failure, or a bridge failure occurs, even in the case of mounting of an electronic component of an extremely small size (for example, not more than 0.6 mm×0.3 mm). Therefore, this enables mounting the electronic component of extremely small size on the wiring substrate with high reliability and high yield.

The electronic component device of the present invention is manufactured by temporarily fixing the electronic component on the wiring substrate, and then forming the gold bump on the wiring pattern of side neighborhood of the electronic component by the wire bump method. The formation of the gold bump by the wire bump method can set processing temperature low and also achieve higher bond strength rather than the case of mounting with solder. Therefore, the reliability of the electronic component device can be improved. Moreover, since the solder is not used in the present invention, there are advantages in which a printing apparatus and a reflow apparatus, or the like are not need, thereby cost reduction is achieved, and it can contribute to the reduction of environmental pollutant.

According to one mode of the present invention, the electrical component device may have a structure in which a plurality of electronic components are mounted on the wiring substrate, the gold bump is provided for each of the electrodes of a plurality of electronic components, and a plurality of electronic components may be connected through the wiring pattern.

Also, according to another mode of the present invention, a plurality of electronic components on the wiring substrate may be directly connected through the gold bump arranged therebetween.

As described above, in the present invention, since the electronic component is bonded to the wiring substrate with a gold bump, the electronic component can be mounted on the wiring substrate with high reliability without any problems even if the electronic component is of an extremely small size.

### BRIEF DESCRIPTION OF THE DRAWINGS

FIG. 1 is a cross-sectional view showing capacitor component mounted on a wiring substrate in the prior art.

FIGS. 2A to 2C are views which explain problems when mounting an electronic component of an extremely small size in the prior art.

FIG. 3 is a cross-sectional view showing an electronic component device according to a first embodiment of the present invention.

FIG. 4 is a cross-sectional view showing an electronic component device according to a modification of the first embodiment of the present invention.

FIG. 5 is a cross-sectional view showing an electronic component device according to a second embodiment of the present invention.

FIG. 6 is a perspective view showing a semiconductor device mounted in the second embodiment of the present invention.

FIG. 7 is a cross-sectional view showing an electronic component device according to a modification of the second embodiment of the present invention.

FIG. 8 is a cross-sectional view and a partial plan view showing an electronic component device according to a third embodiment of the present invention.

FIG. 9 is a cross-sectional view and a partial plan view showing an electronic component device according to a fourth embodiment of the present invention.

FIG. 10 is a cross-sectional view and a partial plan view showing an electronic component device according to a fifth embodiment of the present invention.

FIG. 11 is a cross-sectional view and, a partial plan view showing an electronic component device according to a sixth embodiment of the present invention.

FIG. 12 is a cross-sectional view and a partial plan view showing an electronic component device according to a seventh embodiment of the present invention.

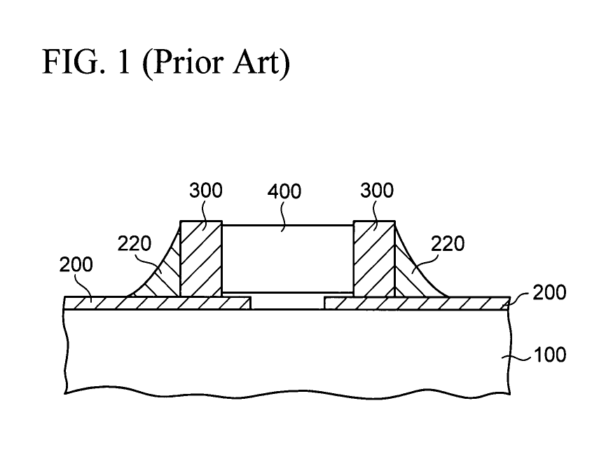

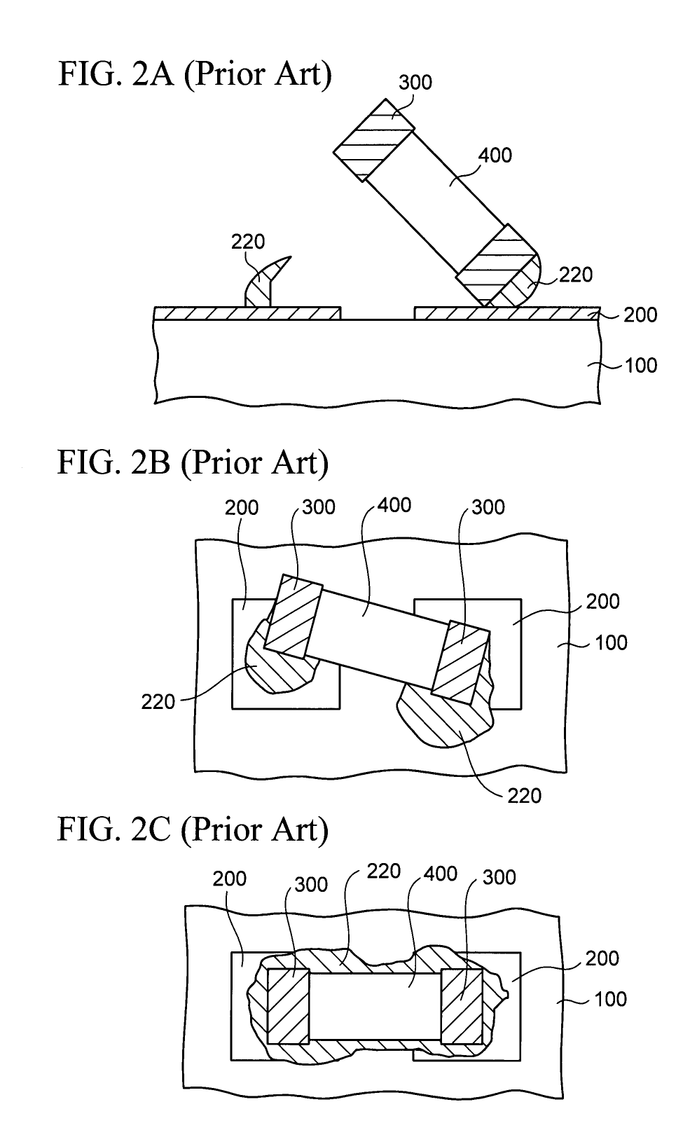

### DESCRIPTION OF THE PREFERRED EMBODIMENTS

Embodiments of the present invention will be explained with reference to the accompanying drawings hereinafter.

### First Embodiment

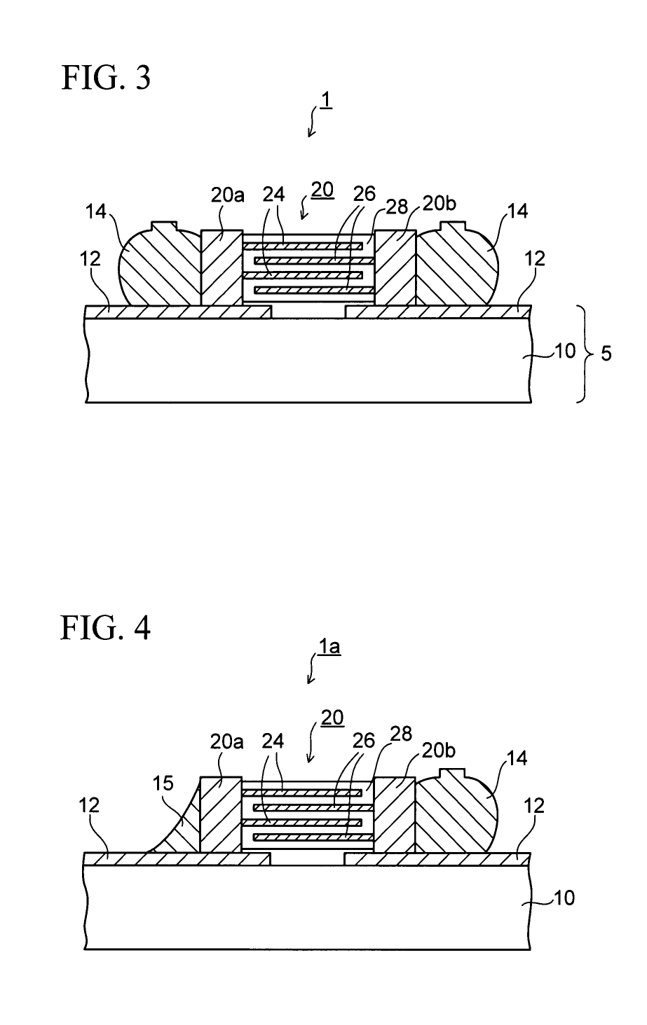

FIG. 3 is a cross-sectional view showing an electronic component device according to a first embodiment of the present invention. An electronic component mounted in the first embodiment is a passive component, and description will be given taking a capacitor component as an example.

As shown in FIG. 3, in an electronic component device 1 according to the first embodiment, a capacitor component 20 is mounted on the wiring pattern 12 of the wiring substrate 5. The wiring substrate 5 is constructed by forming the wiring pattern 12 on the core substrate 10. The wiring substrate 5 may have a structure of a multilayer wiring. Alternatively, the wiring substrate 5 may have a structure in which the wiring patterns 12 are formed on both faces of the core substrate 10, and are connected to each other through a through-hole conductive layer.

The capacitor component 20 is a multilayer capacitor chip, and a capacitor section is constructed by stacking a plurality of first electrode layers 24 and a plurality of second electrode layers 26 via dielectric layers 28 therebetween. A plurality of first electrode layers 24 are connected to a first electrode 20a at one end side, and a plurality of second electrode layers 26 are connected to a second electrode 20b at the other end side.

The capacitor component 20 is arranged on the wiring pattern 12 in a manner that the first electrode 20a and the second electrode 20b are aligned side by side. Moreover, gold bumps 14 which are bonded to the first electrode 20a and the second electrode 20b and the wiring pattern 12 are respectively formed on the wiring pattern 12 of each side neighborhood of the first electrode 20a and the second electrode 20b of the capacitor component 20. Thereby, the first electrode 20a and the second electrode 20b of the capacitor component 20 are electrically connected to the wiring pattern 12 of the wiring substrate 5 through the gold bumps 14.

The gold bumps 14 are formed by a wire bump method (or a wire bonding method), after the capacitor component 20 is temporarily fixed to be aligned on the wiring pattern 12 of the wiring substrate 5. Detailed description will be given below. First, a predetermined length of gold wire is drawn out from a capillary of a wire bonder, and an end portion of the gold wire is spherically shaped by electric discharge. Then, the capillary is moved down so that the end spherical portion of the gold wire is disposed on the wiring pattern 12 of side neighborhood of the capacitor component 20, and the end spherical portion is bonded to the wiring pattern 12 as well as the first electrode 20a and the second electrode 20b of the capacitor component 20 by heating and ultrasonic vibration. Then, the gold wire is clamped while the capillary is moved up, and the wire is cut away immediately above the end spherical portion to thereby obtain the gold bump 14.

Incidentally, the capacitor component 20 having a pair of the electrodes 20a and 20b is shown for example in FIG. 3, but a capacitor component having a plurality of electrodes separately arranged on each of the side surfaces thereof may be employed. In this case, a gold bump is independently arranged to each of the plural electrodes of the capacitor component. Alternatively, a passive component, such as a resistor component or an inductor component, having electrodes on the side surfaces thereof may be employed.

According to the electronic component device 1 according to the first embodiment, as described above, the gold bumps 14 are formed by the wire bump method in a state that the capacitor component 20 is temporarily fixed on the wiring substrate 5, and the first electrode 20a and the second electrode 20b on the side surfaces of the capacitor component 20 are electrically connected to the wiring pattern 12 of the wiring substrate 5 through the gold bumps 14. Unlike a bonding method using fluidic solder, since the gold bumps 14 hardly flow, and the gold bumps 14 can be independently arranged in the side neighborhood of the temporarily-fixed capacitor component 20, there is no possibility that a lifting failure, a misalignment failure, a bridge failure, or the like occurs.

Therefore, this enables mounting a microminiature electronic component with high reliability and high yield without any problems, even in the case of mounting an electronic component of an extremely small size (of, for example, 0.4 mm×0.2 mm or 0.2 mm×0.1 mm).

Also, in the solder bonding in the prior art, when a repair job for modifying a specified portion on the wiring substrate is carried out, there is a problem that solder is easily to remain on the wiring substrate when the electronic component is detached. However, the gold bumps formed by the wire bump method are easily removed from the wiring substrate when the electronic component is detached. Accordingly, the efficiency and yield of the repair job can be increased. Moreover, bonding with the gold bumps by the wire bump method can improve the reliability of bonding of the electronic component, because of achieving higher bond strength than that of the solder bonding.

Further, in the first embodiment, since the solder is not used, a printing apparatus, a reflow apparatus, or the like is not need, thereby cost reduction is achieved, and it can contribute to the reduction of environmental pollutant.

Moreover, the formation of the gold bumps by the wire bump method can reduce damage to the electronic component, and the reliability of the electronic component device can be improved, because processing temperature can be set lower than the solder bonding method.

FIG. 4 shows an electronic component device la according to a modification of the first embodiment. In the electronic component device 1a according to the modification, the first electrode 20a of the capacitor component 20 is bonded with solder 15 to the wiring pattern 12 of the wiring substrate 5, and the second electrode 20b is bonded with the gold bump 14 to the wiring pattern 12. Thus, a form in which a solder bonding and a gold bump bonding are mixed may be employed such that the predetermined electrode 20a out of a plurality of electrodes 20a and 20b on the side surfaces of the capacitor component 20 is bonded by solder 15.

### Second Embodiment

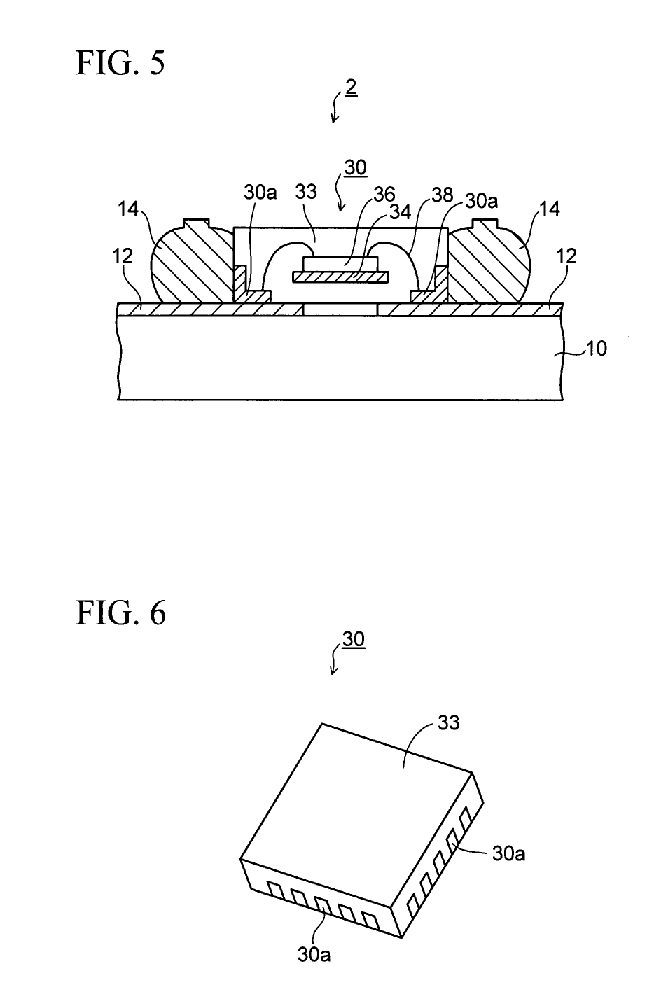

FIG. 5 is a cross-sectional view showing an electronic component device according to a second embodiment of the present invention, and FIG. 6 is a perspective view showing a semiconductor device mounted in the second embodiment. In the second embodiment, the same structural elements as those of the first embodiment are designated by the same reference numerals, and description thereof is omitted.

An electronic component mounted in the second embodiment is an active component, and description will be given taking the semiconductor device as an example. As shown in FIGS. 5 and 6, a semiconductor device 30 has a package structure of QFN(Quad Flatpack Non-leaded package) type. In such semiconductor device 30, a semiconductor chip 36 is fixedly bonded on the die pad 34 and is electrically connected through wires 38 to a plurality of electrodes 30a arranged side by side on the periphery of the semiconductor device 30. The semiconductor chip 36, the wires 38 and the inside surfaces of the electrodes 30a are encapsulated in an encapsulation resin 33. Each of the electrodes 30a of the semiconductor device 30 is arranged to stand upright from a periphery portion of a lower surface of the semiconductor device 30, and outside surface of each electrode 30 is exposed from a periphery portion of a lower surface of the semiconductor device 30 to the side surfaces thereof.

In the second embodiment, as shown in FIG. 5, the semiconductor device 30 as mentioned above is mounted on the wiring pattern 12 of the wiring substrate 5. And, similarly to the first embodiment, the gold bumps 14 which are bonded to the electrodes 30a and the wiring pattern 12 are formed on the wiring pattern 12 of the side neighborhood of the electrodes 30a of the semiconductor device 30. Thereby, the electrodes 30a on the side surfaces of the semiconductor device 30 are electrically connected to the wiring pattern 12 of the wiring substrate 5 through the gold bumps 14.

An electronic component device 2 according to the second embodiment is constructed by this manner. The second embodiment achieves effects similar to those of the first embodiment. In addition, in the wire bump method, the gold bumps 14 can be independently arranged with small pitches of the order of 40 μm or less. Therefore, the gold bumps 14 can be arranged to be bonded to each electrodes 30a of the semiconductor device 30 (FIG. 6) without occurring electrically short circuit between the gold bumps 14, even if the semiconductor device 30 has the small-pitch electrodes 30a.

The processing temperature upon bonding with the solder is between 300 to 330° C. in the prior art. In particular, in a case that a high-performance semiconductor device is mounted, damage to the semiconductor device may become a problem. However, the temperature for the formation of the gold bumps by the wire bump method is between 100 to 175° C., therefore even in the case of mounting the high-performance semiconductor device, it causes no damage to the semiconductor device.

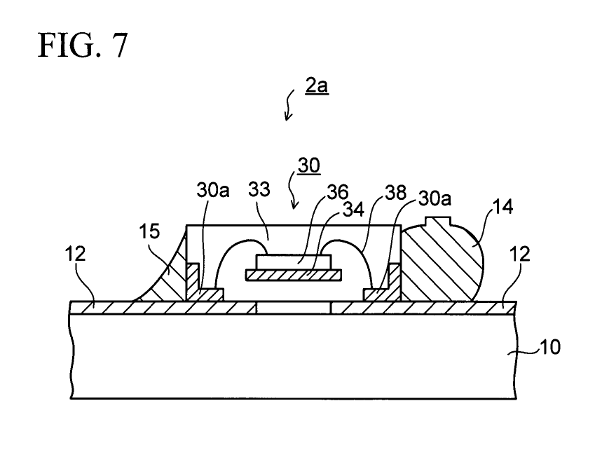

FIG. 7 shows an electronic component device 2a according to a modification of the second embodiment. As shown in FIG. 7, in the electronic component device 2a according to the modification, a predetermined electrode 30a out of a plurality of electrodes 30a arranged on the side surfaces of the semiconductor device 30 is bonded with the solder 15 to the wiring pattern 12 of the wiring substrate 5. Also in the second embodiment, a form in which a solder bonding and a gold bump bonding are mixed may be employed such that the predetermined electrode 30a out of a plurality of electrodes 30a formed on the side surfaces of the semiconductor device 30 is bonded with the solder 15.

### Third Embodiment

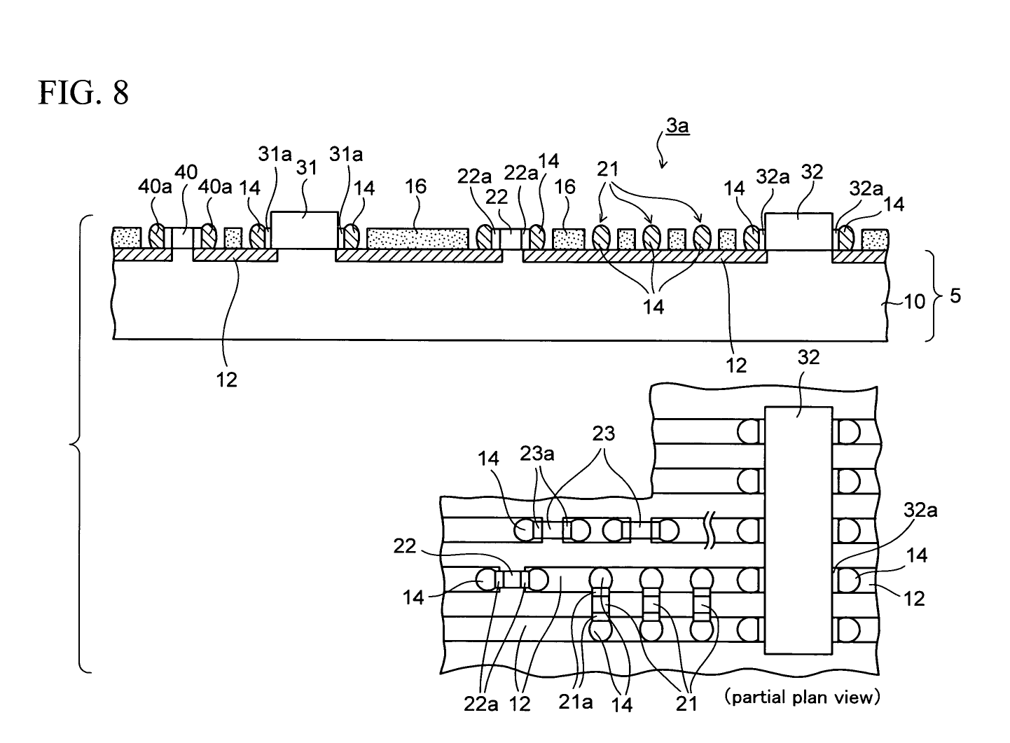

FIG. 8 is a cross-sectional view and a partial plan view showing an electronic component device according to a third embodiment of the present invention. In the third embodiment, an active component and a passive component are mounted in mixed form on the wiring substrate. In the third embodiment, the same structural elements as those of the first embodiment are designated by the same reference numerals, and description thereof is omitted.

As shown in FIG. 8, in an electronic component device 3a according to the third embodiment, a first semiconductor device 31 is mounted on the wiring pattern 12 of the left side of the wiring substrate 5. The first semiconductor device 31 is provided with a plurality of electrodes 31a on the side surfaces thereof, similarly to the semiconductor device 30 according to the second embodiment. And the gold bumps 14 similar to the second embodiment are formed on the wiring pattern 12 of the side neighborhood of the electrodes 31a. Thereby, the electrodes 31a of the first semiconductor device 31 are electrically connected to the wiring pattern 12 through the gold bumps 14.

An inductor component 40 provided with a pair of electrodes 40a on the side surfaces thereof is mounted on the wiring pattern 12 connected to the first semiconductor device 31. Also in the inductor component 40, the gold bumps 14 are formed on the wiring pattern 12 of the side neighborhood of the electrodes 40a, and thereby the electrodes 40a of the inductor component 40 are electrically connected to the wiring pattern 12 through the gold bumps 14. The first semiconductor device 31 has the function of a power supply controller, and the inductor component 40 is interposed in a power supply line to function as an anti-noise filter.

Further, a second semiconductor device 32 provided with a plurality of electrodes 32a on the side surfaces thereof is mounted on the wiring pattern 12 of the right side of the wiring substrate 5, and the electrodes 32a of the second semiconductor device 32 are electrically connected to the wiring pattern 12 through the gold bumps 14 provided on the wiring pattern 12 of the neighborhood of the electrodes 32a.

Referring additionally to the partial plan view of FIG. 8, further, three first capacitor components 21 each having a pair of electrodes 21a are arranged side by side on two wiring patterns 12 connected to the second semiconductor device 32. The electrodes 21a of the capacitor components 21 having the same electrical polarity (or positive or negative polarity) are arranged on one of the two wiring patterns 12, and the electrodes 21a of the opposite polarity are arranged on the other wiring pattern 12.

The gold bumps 14 are arranged on the wiring patterns 12 of the side neighborhood of the pair of the electrodes 21a of each of the first capacitor components 21, and thereby the electrodes 21a of the first capacitor components 21 are electrically connected to the wiring patterns 12 through the gold bumps 14. In this manner, the three first capacitor components 21 are electrically connected in parallel through the gold bumps 14 and the wiring patterns 12.

Further, one of electrodes 22a of a second capacitor component 22 is connected through the gold bump 14 to the wiring pattern 12 connected to the second semiconductor device 32 and the first capacitor components 21. Moreover, the other electrode 22a of the second capacitor component 22 is connected through the gold bump 14 to the wiring pattern 12 connected to the first semiconductor device 31.

Moreover, each of electrodes 23a of two third capacitor components 23, which are different in electrical polarity are arranged to face each other on the wiring pattern 12 of the wiring substrate 5, and the two third capacitor components 23 are mounted as electrically connected in series. The electrodes 23a of the third capacitor components 23 are likewise electrically connected to the wiring pattern 12 through the gold bumps 14.

The second semiconductor device 32 functions as a CPU (Central Processing Unit) and the first capacitor components 21 connected thereto function as decoupling capacitors to reduce high-frequency noise.

Moreover, solder resists 16 are formed in regions around the first and second semiconductor devices 31 and 32, the inductor component 40 and the first, second and third capacitor components 21, 22 and 23. The regions between the solder resists 16 and the electronic components may be filled with a resin and thereby encapsulated therein. Incidentally, the solder resists 16 are omitted from the partial plan view of FIG. 8.

In the third embodiment, as described above, a plurality of electronic components (namely, the first and second semiconductor devices 31 and 32, the inductor component 40 and the first, second and third capacitor components 21, 22 and 23) are mounted on the wiring substrate 5, and the gold bump 14 is provided for each of the electrodes of the electronic components. In this manner, a plurality of electronic components are connected each other through the gold bumps 14 and the wiring patterns 12.

In the electronic component device 3a according to the third embodiment, even if various electronic components of extremely small size are used, the electronic components can be mounted on the wiring substrate 5 with high reliability by the reason mentioned above. Accordingly it can easily meet demands for high density and high performance of the electronic component device.

Incidentally, a form in which, besides the capacitor components and the inductor components, various passive components such as a resistor component are mounted in the same manner may be employed.

### Fourth Embodiment

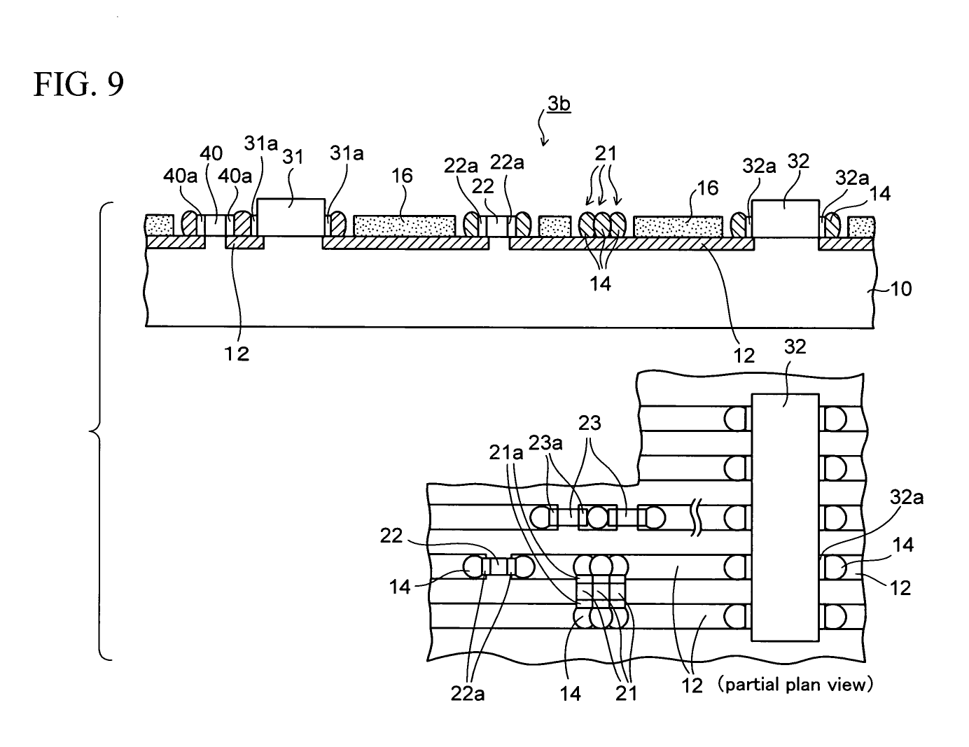

FIG. 9 is a cross-sectional view and a partial plan view, showing an electronic component device according to a fourth embodiment of the present invention. In the third embodiment mentioned above (FIG. 8), a plurality of electronic components are connected through the wiring patterns 12. As shown in FIG. 9, in an electronic component device 3b according to the fourth embodiment, the electrode 31a of the first semiconductor device 31 is connected directly to the electrode 40a of the inductor component 40 through the gold bump 14.

Referring additionally to the partial plan view of FIG. 9, moreover, the three first capacitor components 21 connected in parallel are arranged in contact with each other, and the gold bumps 14 are arranged in the side neighborhood of the electrodes 21a of the first capacitor components 21. In other words, the three first capacitor components 21 are directly connected in parallel through the gold bumps 14 without the use of the wiring patterns 12.

Further, one gold bump 14 is arranged between the electrodes 23a, facing each other, of the two third capacitor components 23 connected in series, and the two third capacitor components 23 are directly connected in series through the gold bump 14 without the use of the wiring pattern 12.

As mentioned above, in a portion where the passive components each having a pair of electrodes at both ends are electrically connected in series, the electrodes of a plurality of passive components, facing each other, may be directly connected through the gold bump. Moreover, in a portion where the electrodes of the passive components each having a pair of electrodes at both ends are electrically connected in parallel as arranged side by side to lateral direction, a plurality of passive components may be directly connected through the gold bumps bonded to each other by arranging a plurality of passive components in contact with each other and providing the gold bumps for each individual electrode. Since other structural elements are the same as those of the third embodiment (see FIG. 8), description thereof is omitted.

In the fourth embodiment, the inductor component 40 can achieve its full performance since the first semiconductor device 31 is connected directly to the inductor component 40 through the gold bump 14. Moreover, capacitor characteristics can be improved since the first capacitor components 21 connected in parallel are directly connected through the gold bumps 14 and the third capacitor components 23 connected in series are directly connected through the gold bump 14.

### Fifth Embodiment

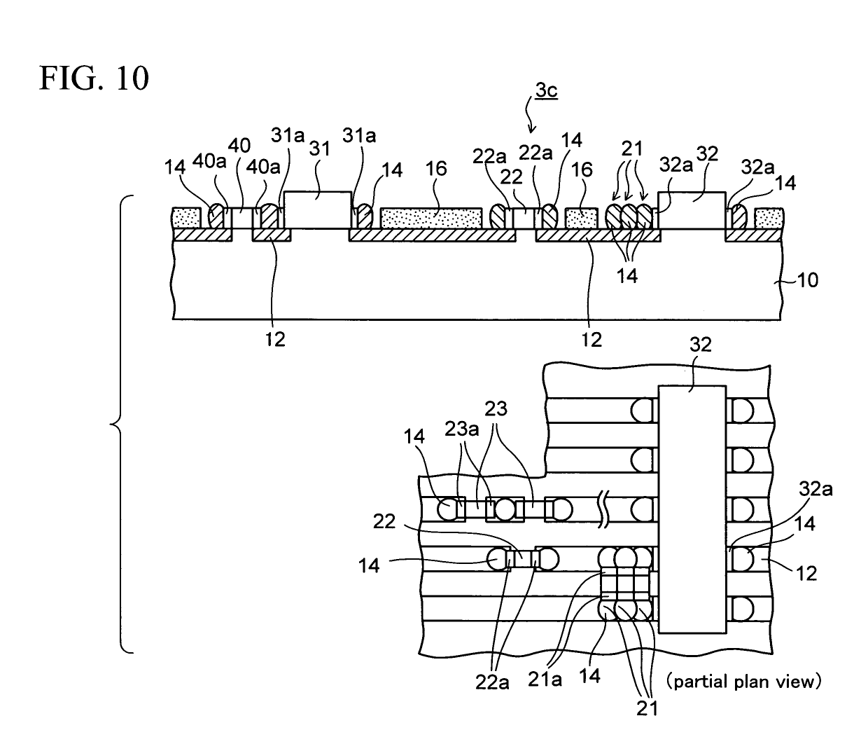

FIG. 10 is a cross-sectional view and a partial plan view, showing an electronic component device according to a fifth embodiment of the present invention. As shown in FIG. 10, in an electronic component device 3c according to the fifth embodiment, the three first capacitor components 21 connected in parallel according to the fourth embodiment mentioned above (FIG. 9) are arranged in contact with the second semiconductor device 32, and the electrodes 21a of the first capacitor components 21 are connected directly to the electrodes 32a of the second semiconductor device 32 through the gold bumps 14.

Since other configurations are the same as those of the fourth embodiment (FIG. 9), description thereof is omitted.

In the fifth embodiment, the three first capacitor components 21 connected in parallel are connected directly to the second semiconductor device 32 through the gold bumps 14. This enables achieving extremely low parasitic inductance, as compared to a connection method using the wiring pattern. Therefore, the first capacitor components 21 achieve a more sufficient performance to function as the decoupling capacitors for the second semiconductor device 32 that operates at high speed.

### Sixth Embodiment

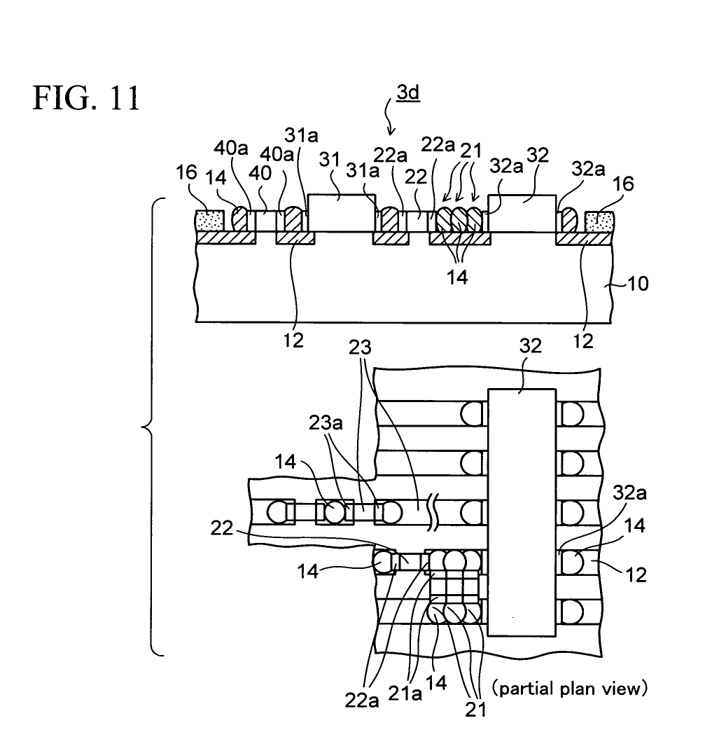

FIG. 11 is a cross-sectional view and a partial plan view, showing an electronic component device according to a sixth embodiment of the present invention. As shown in FIG. 11, in an electronic component device 3d according to the sixth embodiment, the second capacitor component 22 according to the fifth embodiment mentioned above (FIG. 10) is arranged in the neighborhood of the first capacitor components 21, and the electrode 22a of the second capacitor component 22 is connected directly to the electrodes 21a of the first capacitor components 21 through the gold bumps 14. Further, the electrode 22a of the second capacitor component 22 is connected directly to the electrode 31a of the first semiconductor device 31 through the gold bump 14. Since other configurations are the same as those of the fifth embodiment (FIG. 10), description thereof is omitted.

### Seventh Embodiment

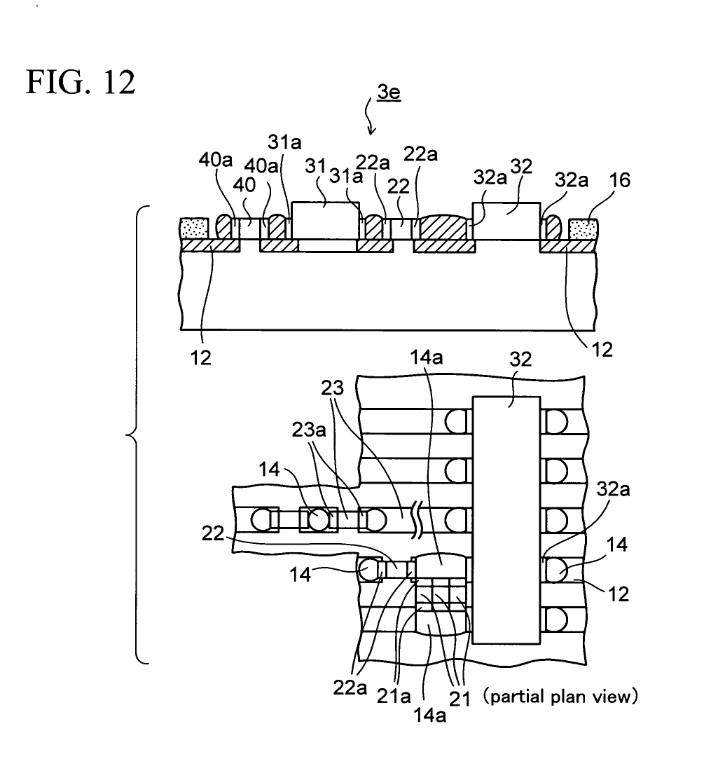

FIG. 12 is a cross-sectional view and a partial plan view, showing an electronic component device according to a seventh embodiment of the present invention. In the sixth embodiment mentioned above (FIG. 11), the individual gold bump 14 is respectively arranged to each of the pair of the electrodes 21a of the three first capacitor components 21 connected in parallel. As shown in FIG. 12, in an electronic component device 3e according to the seventh embodiment, common gold bumps 14a bonded collectively to the pair of the electrodes 21a of each of the three first capacitor components 21 are arranged and connected in parallel. The three first capacitor components 21 are connected directly to the electrodes 32a of the second semiconductor device 32 and the electrode 22a of the second capacitor component 22 through the common gold bumps 14a.

Since other configurations are the same as those of the sixth embodiment (FIG. 11), description thereof is omitted.

As mentioned above, as explained in the fourth to seventh embodiments (FIGS. 9 to 12), a predetermined portion or all of a plurality of electronic components mounted on the wiring substrate 5 may be directly connected through the gold bump 14 without the use of the wiring pattern 12.

Moreover, a predetermined portion of the electrodes of a plurality of electronic components may be bonded with solder, or all electrodes of the electronic components may be connected to the wiring pattern through the gold bumps without any use of solder bonding.

What is claimed is:

1. An electronic component device, comprising:
a wiring substrate having a wiring pattern;
an electronic component mounted on the wiring pattern of the wiring substrate and provided with an electrode on a side surface thereof; and
a gold bump provided on the wiring pattern of side neighborhood of the electrode of the electronic component and bonded to the electrode of the electronic component and the wiring pattern,
wherein the electrode of the electronic component is electrically connected to the wiring pattern through the gold bump.

2. The electronic component device according to claim 1, wherein the gold bump is formed by wire bump method.

3. The electronic component device according to claim 1, wherein the electronic component is anyone, or a combination of two or more selected from the group consisting of a semiconductor device, a capacitor component, an inductor component and a resistor component.

4. The electronic component device according to claim 1, wherein a plurality of electronic components are mounted on the wiring substrate, the gold bump is respectively provided to each of the electrodes of the plurality of electronic components, and the plurality of electronic components are connected through the wiring pattern.

5. The electronic component device according to claim 1, wherein a plurality of electronic components are mounted on the wiring substrate and the plurality of electronic components are directly connected through the gold bump arranged therebetween.

6. The electronic component device according to claim 1, wherein
the electronic component includes a passive component having a pair of electrodes, and
in a portion where the electrodes, which have different electrical polarities, of a plurality of said passive components are arranged to face each other and electrically connected in series, the electrodes, which face each other, of the plurality of passive components are directly connected with the gold bump.

7. The electronic component device according to claim 1, wherein
the electronic component includes a passive component having a pair of electrodes, and
in a portion where the electrodes, which have the same electrical polarity, of a plurality of said passive components are arranged side by side to lateral direction and electrically connected in parallel, the plurality of passive components are arranged in contact with each other, and either the individual gold bump is provided to each of electrodes, or a common gold bump is collectively provided to each of a pair of the electrodes respectively.

8. A method of mounting an electronic component, comprising the steps of:
preparing a wiring substrate having a wiring pattern;
temporarily fixing an electronic component on the wiring pattern of the wiring substrate, the electronic component being provided with an electrode on a side surface of thereof, and;
forming a gold bump, by a wire bump method, on the wiring pattern of side neighborhood of the electrode of the electronic component, thereby electrically connecting the electrode of the electronic component to the wiring pattern through the gold bump.

9. The method of mounting an electronic component according to claim 8, wherein the electronic component is anyone, or a combination of two or more selected from the group consisting of a semiconductor device, a capacitor component, an inductor component and a resistor component.

10. The method of mounting an electronic component according to claim 8, wherein the electronic component has a plurality of said electrodes, and the gold bumps is independently formed to each of the plurality of electrodes respectively.
